(19) United States
(12) Patent Application Publication
(10) Pub. No.: US 2005/0099238 A1
(43) Pub. Date: May 12, 2005

(54) Method for manufacturing a crystal oscillator and a crystal oscillator

(76) Inventors: Sampo Sakari Aallos, Tampere (FI); Raimo Antero Makela, Lohja (FI); Klaus Turhanen, Muijala (FI); Karri Valvisto, Kantvik (FI)

Correspondence Address: STITES & HARBISON PLLC, 1199 NORTH FAIRFAX STREET, SUITE 900, ALEXANDRIA, VA, 22314, US

(21) Appl. No.: 10/433,955

(22) PCT Filed: Dec. 7, 2001
(86) PCT No.: PCT/FI01/01070

(30) Foreign Application Priority Data
Dec. 7, 2000 (FI) 20002682

(51) Int. Cl. H03B 5/32

(52) U.S. Cl. 331/158

(57) ABSTRACT

A crystal oscillator module and method to manufacture the crystal oscillator module by sandwich method on a bottom-base, as a printed board (4), where the oscillator crystal (1) is for instance fixed onto the surface of the printed district board (4). On the opposite surface of the printed district board, at least partly at oscillator crystal (1), in order to increase the thickness of the printed district board (4), one or several elements (5) are fixed, by means of which a cavity is formed for components included module.

This invention relates to a crystal oscillator module and its manufacturing method in utilizing the sandwich structure of printed circuit boards.

Previously known is a ceramic sandwich structure, where the printed disc board ceramic material includes a gap arrangement adapted to the oscillator, in other words a cavity for necessary components. In addition the crystal, closely joined to the cavity bottom are the necessary components, whereat they are at least partly protected. The crystal is connected to the cavity together with other components or separately.

Also known is a cavity carried out by printed circuit board technique that is made by pressing the sandwiches, such as printed circuit boards, on another, whereat there is in the other board an opening made beforehand or openings forming cavities, i.e. gaps, when the sandwiches are together. The openings in the other board can also be made even after gluing, for instance by laser beam cutting, but it is a more complicated procedure. The disadvantage of gluing is that the glue spreads in large extent, also on the bottom of the cavity and reduces the lay-out space of components. Further, the glue can spread out as a thin film on the bottom of the cavity preventing reliable fixing of components.

For instance, known from patent publication U.S. Pat. No. 6,160,458 is an oscillator crystal packed onto a printed circuit board, whereat other components and compensation circuits closely included in it are placed in immediate nearness of the crystal component and connected to it by cables. In the solution of the publication there is a conventional printed disc board and in connection with it no cavity is formed for the components.

By means of the manufacturing method as per the invention a new crystal oscillator module of sandwich structure is accomplished and the above presented problems are avoided and the manufacture of the oscillator facilitated. The crystal oscillator is made by sandwich method on a bottom base, e.g. a printed circuit board, whereat the oscillator is, for instance, fixed by gluing or soldering on the surface of the printed circuit board. The method as per the invention is characterized in that on the opposite surface of the printed circuit board, at least partly at the oscillator crystal, in order to increase the thickness of the printed circuit board, one or several elements are attached by means of which cavity is formed for the components included in the module.

The crystal oscillator module as per the invention is characterized in that on the opposite side of the printed circuit board, at least partly at the oscillator crystal, in order to increase the thickness of the printed circuit board, one or several elements are fixed, which are adapted to form a cavity for the components included in the module.

The advantage of the manufacturing method and the advantage of the crystal oscillator module made by a method as per the invention is that in using the invention, at least at the oscillator crystal simply a sandwich structure in the printed circuit board is achieved, whereat a cavity is formed in the printed circuit board partly protecting the crystal oscillator module. The cavity is formed by gluing or soldering on the circuit board surface an additional sandwich so that it gets substantially only about the oscillator components and forms there an annular edge. Gluing and soldering of the edge is easy and will not disturb the use of the surfaces of other printed circular boards.

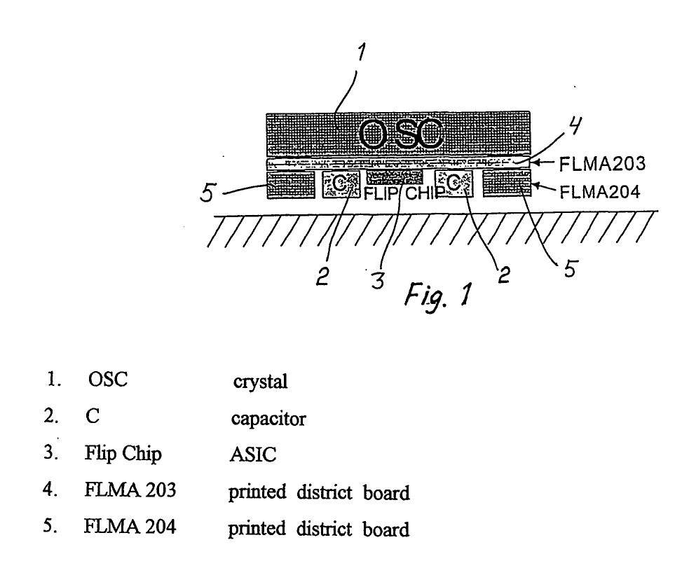

In the following the invention is disclosed with reference to the enclosed drawing FIG. 1, which shows a crystal oscillator module as a sectional view.

FIG. 1 is an example of the crystal oscillator module formed on a bottom-base 4, which is of printed circuit board material or other material suitable as connection material. Into base 4 necessary components are fixed by soldering or gluing, of which for example condensers are presented by reference number 2 and flip chips by reference number 3.

To the edge area an element of printed disc board material or of conducting or non-conducting homogenous material is installed, such as elevating pieces 5 according to FIG. 1 or one elevating flat ring on the oscillator module area The edge forming a cavity can be accomplished with one flat ring that can be glued or soldered or for instance with four elements 5 that can be glued or soldered and which, as four edges of the cavity, form a quadrangle. If there will be more oscillators, then for instance on the base 4 a uniform elevating board with openings is fixed on the area of several oscillators. On the opposite side of base 4 and in regard to components 2 and 3 a crystal or another resonator is installed by soldering or gluing.

The size of base 4 is not limited to the size of crystal 1 but its size can vary as occasion demands. However, its minimum size is according to FIG. 1.

1. A method to produce a crystal oscillator module by the sandwich method on a bottom-base, e.g. a printed district board (4), where for instance the oscillator crystal (1) is fixed by gluing onto the surface of the printed district board (4), characterized in that on the opposite surface of the printed district board, at least partly at oscillator crystal (1), in order to increase the thickness of the printed district board (4), one or several elements (5) are fixed, by means of which a cavity is formed for components (2,3) included in the crystal oscillator module.

2. A method according to claim 1 characterized in that element (5) is fixed by gluing or soldering.

3. A method according to claim 1 characterized in that a plurality of cavities is formed by means of one element (5).

4. A crystal oscillator module produced by the sandwich method, where an oscillator crystal (1) is fixed on a board base, e.g. on the surface of a printed district board (4), characterized in that on the opposite surface of the printed district board (4), at least partly at oscillator crystal (1), in order to increase the thickness of printed district board (4), one or several elements (5) have been fixed, which are adapted to form a cavity for components (2,3) included in the crystal oscillator module.

5. A crystal oscillator module according to claim 4 characterised in that element (5) is of printed district board material or of conducting or non-conducting homogenous material.
